(19) United States
(12) Patent Application Publication
(10) Pub. No.: US 2019/0057026 A1
(43) Pub. Date: Feb. 21, 2019

(54) DATA STORAGE DEVICE AND OPERATING METHOD THEREOF

(71) Applicant: SK hynix Inc., Gyeonggi-do (KR)

(72) Inventor: Jeen PARK, Gyeonggi-do (KR)

(21) Appl. No.: 16/031,717

(22) Filed: Jul. 10, 2018

(30) Foreign Application Priority Data
Aug. 18, 2017 (KR) 10-2017-0105014

(51) Int. Cl. G06F 12/02; G11C 29/02; G11C 11/56; G06F 3/06

(52) U.S. Cl. CPC G06F 12/0246; G06F 3/0688; G11C 11/5635; G11C 29/021

(57) ABSTRACT

A data storage device includes a nonvolatile memory device including a plurality of planes each of which includes a plurality of memory units; and a controller configured to determine a plane distribution of one or more first planes which include one or more first memory units, determine whether the plane distribution satisfies a predetermined condition, select a memory unit in each of one or more second planes, as a second memory unit, depending on the determination result of the satisfaction of the predetermined condition, and perform a read-access in the first memory units and the second memory units simultaneously.

### CROSS-REFERENCES TO RELATED APPLICATION

The present application claims priority under 35 U.S.C. § 119(a) to Korean application number 10-2017-0105014, filed on Aug. 18, 2017, which is incorporated herein by reference in its entirety.

### BACKGROUND

### 1. Technical Field

Various embodiments generally relate to a data storage device, and, more particularly, to a data storage device including a nonvolatile memory device.

### 2. Related Art

A data storage device may be configured to store data provided from an external device in response to a write request from the external device. Also, the data storage device may be configured to provide stored data to the external device in response to a read request from the external device. The external device may be an electronic device capable of processing data and may include a computer, a digital camera or a mobile phone. The data storage device may operate by being built in the external device, or may operate by being manufactured in a separable form and being coupled to the external device.

### SUMMARY

In an embodiment, a data storage device may include: a nonvolatile memory device including a plurality of planes each of which includes a plurality of memory units; and a controller configured to determine a plane distribution of one or more first planes which include one or more first memory units, determine whether the plane distribution satisfies a predetermined condition, select a memory unit in each of one or more second planes as a second memory unit depending on the determination result of the satisfaction of the predetermined condition, and perform a read-access in the first memory units and the second memory units simultaneously.

In an embodiment, a method for operating a data storage device including a nonvolatile memory device having a plurality of planes each of which includes a plurality of memory units may comprise: determining a plane distribution of one or more first planes which include one or more first memory units; determining whether the plane distribution satisfies a predetermined condition; selecting a memory unit in each of one or more second planes as a second memory unit depending on the determination result of the satisfaction of the predetermined condition; and performing read-access in the first memory units and the second memory units simultaneously.

In an embodiment, a data storage device may include: a nonvolatile memory device including a plurality of planes, and configured to support a multi-plane read operation for the plurality of planes; and a controller configured to process the multi-plane read operation by merging a host read operation and a background read operation, wherein host target memory units of the host read operation and background target memory units of the background read operation have different offset values.

### BRIEF DESCRIPTION OF THE DRAWINGS

FIG. 1 is a block diagram illustrating an example of a data storage device in accordance with an embodiment.

FIG. 2 is a block diagram illustrating an example of the detailed configuration of a nonvolatile memory device in accordance with the embodiment.

FIG. 3A is an exemplary diagram of a method for a read operation for target planes of the nonvolatile memory device in accordance with the embodiment.

FIG. 3B is an exemplary diagram of a method for a read operation for target planes of the nonvolatile memory device in accordance with the embodiment.

FIG. 3C is an exemplary diagram of a method for a read operation for target planes of the nonvolatile memory device in accordance with the embodiment.

FIG. 4 is an exemplary diagram of a method for merging read requests by a read merge circuit in accordance with the embodiment.

FIG. 5 is an exemplary diagram of a method for a sequential read operation by the read merge circuit in accordance with the embodiment.

FIG. 6 is an exemplary flow chart of a method for how to operate the data storage device of FIG. 1 in accordance with an embodiment.

FIG. 7 illustrates a data processing system including a solid state drive (SSD) in accordance with an embodiment.

FIG. 8 illustrates a data processing system including a memory system in accordance with an embodiment.

FIG. 9 illustrates a data processing system including a memory system in accordance with an embodiment.

FIG. 10 illustrates a network system including a memory system in accordance with an embodiment.

FIG. 11 is a block diagram illustrating a nonvolatile memory device included in a memory system in accordance with an embodiment.

### DETAILED DESCRIPTION

Hereinafter, a memory system and an operating method thereof according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology used is for describing particular embodiments only and is not intended to limit the scope of the present invention.

It will be further understood that when an element is referred to as being “connected to” or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The phrase “at least one of . . . and . . . ,” when used herein with a list of items, means a single item from the list or any combination of items in the list. For example, “at least one of A, B, and C” means, only A, or only B, or only C, or any combination of A, B, and C.

The term “or” as used herein means either one of two or more alternatives but not both nor any combinations thereof.

As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art, and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted that in some instances, as would be apparent to those skilled in the relevant art, an element also referred to as a feature described in connection with one embodiment may be used singly or in combination with other elements of another embodiment, unless specifically indicated otherwise.

Hereinafter, the various embodiments of the present invention will be described in detail with reference to the attached drawings.

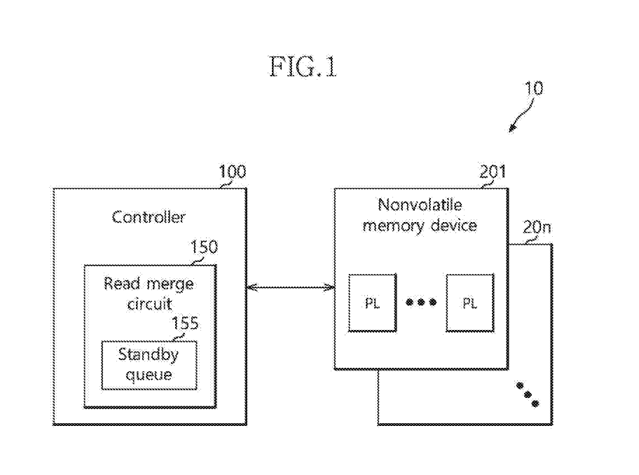

FIG. 1 is a block diagram illustrating an example of a data storage device 10 in accordance with an embodiment.

The data storage device 10 may be configured to store data provided from an external host device in response to a write request from the host device. Also, the data storage device 10 may be configured to provide stored data to the host device, in response to a read request from the host device.

The data storage device 10 may be configured by a Personal Computer Memory Card International Association (PCMCIA) card, a compact flash (CF) card, a smart media card, a memory stick, a multimedia card in the form of MMC, eMMC, RS-MMC and MMC-micro, a secure digital card in the form of SD, mini-SD and micro-SD, a universal flash storage (UFS), or a solid state drive (SSD).

The data storage device 10 may include a controller 100 and a plurality of nonvolatile memory devices 201 to 20n.

The controller 100 may control general operations of the data storage device 10. The controller 100 may store data in the nonvolatile memory devices 201 to 20n in response to a write request transmitted from the host device, and may read data stored in the nonvolatile memory devices 201 to 20n and output read data to the host device in response to a read request transmitted from the host device.

Hereinafter, a read operation that the controller 100 performs in response to a read request transmitted from the host device will be referred to as a host read operation. Data to be read or read through the host read operation will be referred to as host read data. A memory unit for which the host read operation is performed will be referred to as a host target memory unit.

Meanwhile, the controller 100 may perform a read operation for a background operation of the data storage device 10 regardless of a request from the host device. The background operation may include, for example, a garbage collection operation, a wear leveling operation or a read reclaim operation.

Hereinafter, a read operation that the controller 100 performs for a background operation will be referred to as a background read operation. Data to be read or read through the background read operation will be referred to as background read data. A memory unit for which the background read operation is performed will be referred to as a background target memory unit.

The controller 100 may include a read merge circuit 150. The read merge circuit 150 may merge read operations and may perform a read-access of target memory units of the merged read operations simultaneously. Read operations may be merged without distinguishing a host read operation and a background read operation.

In detail, the read merge circuit 150 may determine the plane distribution of one or more first planes which include one or more first memory units of the nonvolatile memory device 201. For example, the first memory units may be host target memory units. That is, the read merge circuit 150 may determine the plane distribution of host target memory units before performing a host read operation.

The plane distribution of the first planes may mean a state of a plane distribution of a plurality of planes PL which are included in the nonvolatile memory device 201. The first planes including the first memory units may be different from each other or from one another, and therefore, may constitute a certain plane distribution.

The read merge circuit 150 may determine whether the plane distribution of the first planes corresponds to a maximum plane distribution. The maximum plane distribution may be constituted by the maximum planes which may be read-accessed simultaneously by the nonvolatile memory device 201 through a multi-plane read operation.

When the plane distribution of the first planes corresponds to the maximum plane distribution, the read merge circuit 150 may perform the multi-plane read operation for the first memory units.

However, when the plane distribution of the first planes does not correspond to the maximum plane distribution, the read merge circuit 150 may select a memory unit in each of second planes of the nonvolatile memory device 201. The second planes may not overlap with the first planes. In other words, the second planes may not be included in the plane distribution of the first planes. The second planes may be the remaining planes except the first planes among the planes which constitute the maximum plane distribution.

The memory units selected in the respective second planes, that is, second memory units may be background target memory units. When one or more background read operations are scheduled for the second planes, the read merge circuit 150 may select some among the background target memory units as the second memory units for the background read operations.

The read merge circuit 150 may merge the host read operation for the first memory units and the background read operation for the second memory units. In detail, the read merge circuit 150 may perform a read-access of the first memory units and the second memory units simultaneously through the multi-plane read operation. The host read data stored in the first memory units and the background read data stored in the second memory units may be read simultaneously.

Meanwhile, the second memory units may have different offset values from the first memory units. Namely, the positions of the first memory units and the second memory units may be independent.

The read merge circuit 150 may include a standby queue 155. The standby queue 155 may include scheduled background read operations. Thus, the read merge circuit 150 may select the second memory units from the standby queue 155 to perform a read-access with the first memory units simultaneously, thereby constituting the maximum plane distribution.

According to an embodiment, the controller 100 may process the multi-plane read operation by merging the background read requests stored in the standby queue 155 to constitute the target planes of background target memory units with the maximum plane distribution. Accordingly, the data processing efficiency of the nonvolatile memory device 201 may be maximized.

The plurality of nonvolatile memory devices 201 to 20n may store data transmitted from the controller 100 and may read stored data and transmit read data to the controller 100 according to the control of the controller 100.

Each of the nonvolatile memory devices 201 and 20n may include a plurality of planes PL which are simultaneously accessible. Each of the nonvolatile memory devices 201 and 20n may perform a multi-plane read operation for a simultaneous read-access of the plurality of planes PL according to the control of the controller 100.

A nonvolatile memory device may include a flash memory, such as a NAND flash or a NOR flash, a Ferroelectrics Random Access Memory (FeRAM), a Phase-Change Random Access Memory (PCRAM), a Magnetoresistive Random Access Memory (MRAM), a Resistive Random Access Memory (ReRAM), and the like.

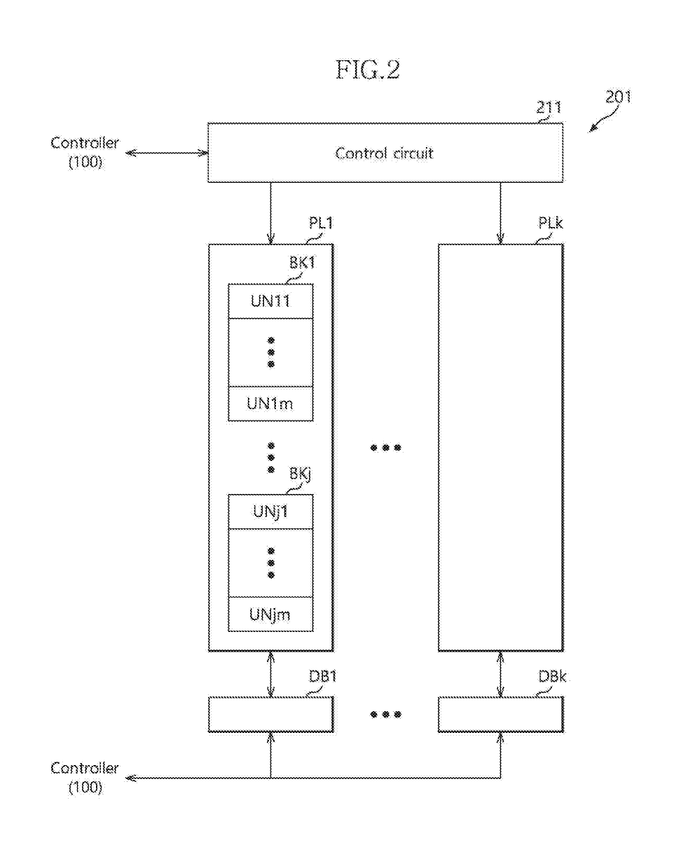

FIG. 2 is a block diagram illustrating an example of a detailed configuration of the nonvolatile memory device 201 in accordance with the embodiment. The nonvolatile memory devices 201 to 20n of FIG. 1 may be configured and operate in substantially the same manner as the nonvolatile memory device 201.

Referring to FIG. 2, the nonvolatile memory device 201 may include a control circuit 211, a plurality of data buffers DB1 to DBk and a plurality of planes PL1 to PLk.

The control circuit 211 may perform a write operation to store data in the plurality of planes PL1 to PLk according to the control of the controller 100. Also, the control circuit 211 may perform a read operation to read data from the plurality of planes PL1 to PLk, according to the control of the controller 100.

A target plane may be a plane which is to be accessed or is accessed by the control circuit 211 among the plurality of planes PL1 to PLk. A target memory unit may be a concrete memory unit which is to be accessed or is accessed by the control circuit 211 among the plurality of memory units included in the target plane.

In order to perform a write operation and a read operation, the control circuit 211 may simultaneously select one or more target planes among the plurality of planes PL1 to PLk, and may access concrete positions designated by the controller 100, that is, target memory units in the respective selected target planes. An operation of simultaneously read-accessing one or more target planes may be defined as a multi-plane read operation.

The plurality of data buffers DB1 to DBk may correspond to the plurality of planes PL1 to PLk respectively, and may temporarily store data to be transmitted between the plurality of planes PL1 to PLk and the controller 100. In detail, when a write operation is performed, each of the data buffers DB1 to DBk may receive data to be stored in a corresponding plane from the controller 100 and store the data. When a read operation is performed, each of the data buffers DB1 to DBk may store the data read from a corresponding plane and transmit the data to the controller 100.

Each of the data buffers DB1 to DBk may be shared by a plurality of memory blocks which are included in a corresponding plane. For example, the data buffer DB1 may temporarily store data to be transmitted between memory blocks BK1 to BKj included in the corresponding plane PL1 and the controller 100.

The planes PL1 to PLk may store the data transmitted from the data buffers DB1 to DBk. Each of the planes PL1 to PLk may include a plurality of memory blocks. When making descriptions by taking the plane PL1 as an example, the plane PL1 may include the plurality of memory blocks BK1 to BKj. The memory blocks BK1 to BKj may share the corresponding data buffer DB1.

Memory block may be a group of memory units by which an erase operation is performed. In other words, when performing an erase operation for a memory block, the nonvolatile memory device 201 may simultaneously erase the data stored in the memory block.

The respective memory blocks BK1 to BKj may be configured in substantially the same way with one another. When making descriptions by taking the memory block BK1 as an example, the memory block BK1 may include a plurality of memory units UN11 to UN1m.

Memory unit may be a group of memories by which a read operation is performed in each of the planes PL1 to PLk. In other words, when performing a read operation, the nonvolatile memory device 201 may select one or more target planes among the planes PL1 to PLk, and may read the data stored in the target memory units of the respective selected target planes. The nonvolatile memory device 201 may read data simultaneously from the target memory units of two or more target planes through a multi-plane read operation. The data read from the target memory units may be stored in corresponding data buffers, respectively.

The memory units UN11 to UN1m may correspond to predetermined offset values, respectively, by the unit of memory block. Each of the memory blocks BK1 to BKj may include memory units of the predetermined offset values. For example, when “m” number of memory units are included in each memory block, each of the memory blocks BK1 to BKj may include memory units corresponding to offset values “1” to “m.”

The offset value of a memory unit may be the address of the memory unit. The offset value may define the position of the memory unit in a memory block. Memory units which have the same offset value in different memory blocks may be present at the same position in the respective corresponding memory blocks. Memory units which have the same offset value in different memory blocks may be coupled to word lines of the same order in the respective corresponding memory blocks.

Summarizing these, the controller 100 may specify a certain memory unit as a target and access the certain memory unit by designating the address of a plane, the address of a memory block and a specified offset value.

Each of the planes PL1 to PLk may be constructed by a plurality of memory cells. Each of the memory cells may store one or more data bits. Depending on the number of data bits to be stored in each memory cell, a group of one or more memory units may correspond to a single word line, and may correspond to a group of memory cells which are coupled to the corresponding word line. The data stored in a certain group of memory units may be the data stored in a corresponding group of memory cells. In order to access a target memory unit, the nonvolatile memory device 201 may access a corresponding group of memory cells by driving a corresponding word line. A memory unit may be a page unit.

When 1 bit is stored in each memory cell, a word line or a group of memory cells which are coupled to the word line may correspond to one memory unit. When 2 bits, that is, LSB (least significant bit) and MSB (most significant bit) data are stored in each memory cell, word lines or groups of memory cells which are coupled to the word lines may correspond to two memory units in which LSB and MSB data are stored, respectively. When 3 bits, that is, LSB, CSB (central significant bit) and MSB data are stored in each memory cell, word lines or groups of memory cells which are coupled to the word lines may correspond to three memory units in which LSB, CSB and MSB data are stored, respectively.

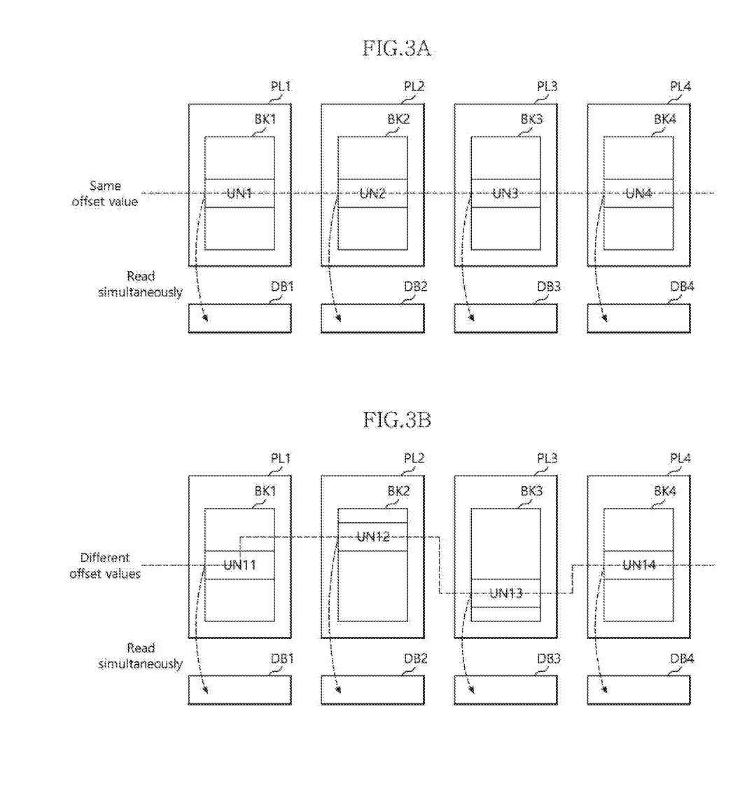

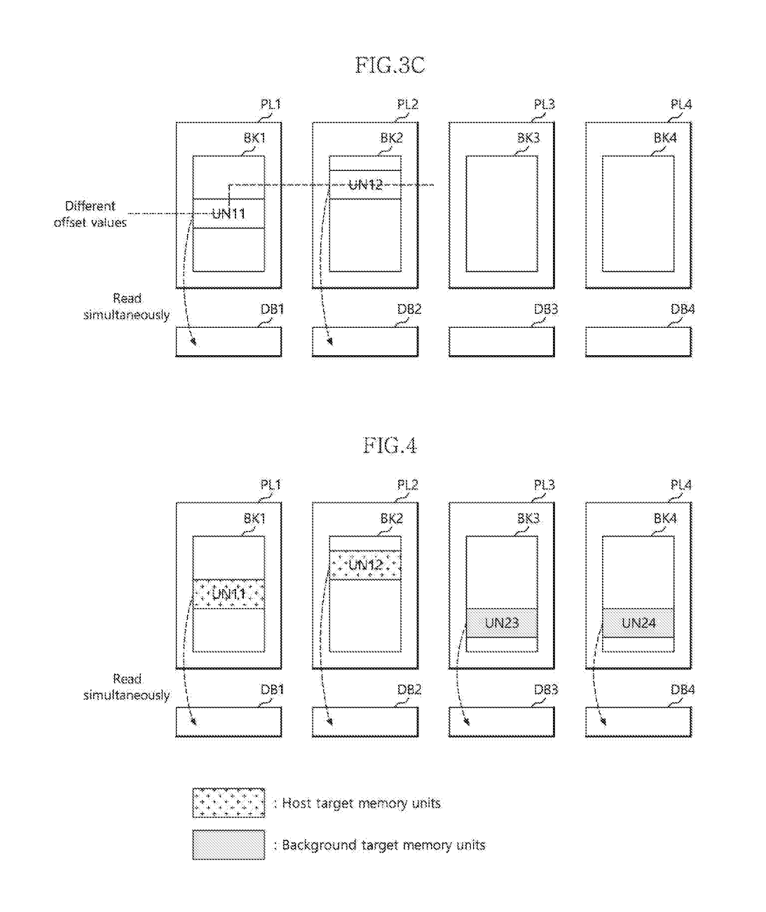

FIG. 3A is an exemplary diagram for a method of a read operation for target planes PL1 to PIA of the nonvolatile memory device 201 in accordance with the embodiment. Hereunder, it is assumed that the nonvolatile memory device 201 includes four planes PL1 to PL4 for example.

The target planes PL1 to PL4 may include target memory blocks BK1, BK2, BK3 and BK4, respectively, which include target memory units UN1, UN2, UN3 and UN4 for the read operation. Namely, one memory block may be selected as a target in each plane, and one memory unit may be selected as a target in the corresponding memory block. The target memory units UN1, UN2, UN3 and UN4 may be accessed simultaneously. That is, when the read operation is performed, the data stored in the target memory units UN1, UN2, UN3 and UN4 may be read simultaneously and be stored in data buffers DB1 to DB4.

Such an operation may be possible when the nonvolatile memory device 201 supports a multi-plane read that read-accesses maximum four planes PL1 to PL4 simultaneously. A maximum plane distribution may mean a distribution in which the nonvolatile memory device 201 is comprised of the planes PL1 to PL4 which are read-accessible simultaneously at the maximum.

The target memory units UN1, UN2, UN3 and UN4 may have the same offset value. When the target memory units UN1, UN2, UN3 and UN4 have the same offset value, the target memory units UN1, UN2, UN3 and UN4 may be present at the same position in the target memory blocks BK1, BK2, BK3 and BK4. When the target memory units UN1, UN2, UN3 and UN4 have the same offset value, the target memory units UN1, UN2, UN3 and UN4 may be coupled to word lines of the same order in the target memory blocks BK1, BK2, BK3 and BK4.

However, as will be described below, according to the embodiment, the target memory units of a read operation may have different offset values.

FIG. 3B is an exemplary diagram for a method of a read operation for target planes PL1 to PL4 of the nonvolatile memory device 201 in accordance with the embodiment.

Referring to FIG. 3B, unlike FIG. 3A, target memory units UN11, UN12, UN13 and UN14 of the target planes PL1 to PL4 may have different offset values. When the target memory units UN11, UN12, UN13 and UN14 have different offset values, the target memory units UN11, UN12, UN13 and UN14 may be present at different positions in target memory blocks BK1, BK2, BK3 and BK4. The nonvolatile memory device 201 may access the target memory units UN11, UN12, UN13 and UN14 simultaneously. That is, when the read operation is performed, the data stored in the target memory units UN11, UN12, UN13 and UN14 may be read simultaneously and be stored in data buffers DB1 to DB4.

FIG. 3C is an exemplary diagram for a method of a read operation for target planes PL1 and PL2 of the nonvolatile memory device 201 in accordance with the embodiment.

Referring to FIG. 3C, unlike FIGS. 3A and 3B, the read operation of the nonvolatile memory device 201 may be performed for only a part of the planes PL1 to PL4. For example, among the planes PL1 to PL4, the planes PL1 and PL2 may be selected as the target planes of the read operation. Target memory units UN11 and UN12 included in target memory blocks BK1 and BK2 of the target planes PL1 and PL2 may be selected for the read operation. The nonvolatile memory device 201 may access the target memory units UN11 and UN12 simultaneously. That is, when the read operation is performed, the data stored in the target memory units UN11 and UN12 may be read simultaneously and be stored in data buffers DB1 and DB2.

However, as shown in FIG. 3C, when the target planes PL1 and PL2 do not constitute the maximum plane distribution of the multi-plane read of the nonvolatile memory device 201, the data processing efficiency of the nonvolatile memory device 201 may not be maximized.

Summarizing these, the nonvolatile memory device 201 may read-access target memory units simultaneously which have the same offset value or different offset values, in one or more target planes. Therefore, by utilizing this feature, data processing efficiency may be maximized when the controller 100 merges different read operations for different target planes, and performs the read operations simultaneously, rather than the controller 100 performing the different read operations separately.

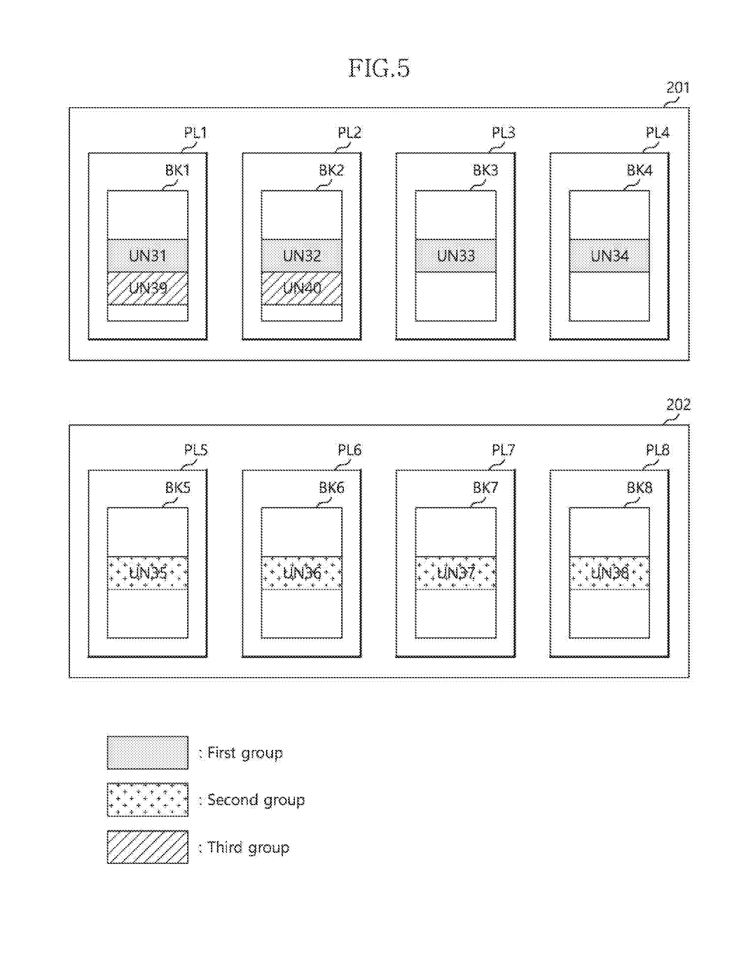

FIG. 4 is an exemplary diagram for a method of merging read requests by the read merge circuit 150 in accordance with the embodiment.

Referring to FIG. 4, for example, the host device may control a host read operation to be scheduled for host target memory units UN11 and UN12. The read merge circuit 150 may determine whether target planes PL1 and PL2 including the host target memory units UN11 and UN12 constitute a maximum plane distribution.

The maximum plane distribution may be constituted by a maximum number of planes for which the nonvolatile memory device 201 may perform a multi-plane read operation simultaneously. For example, when the nonvolatile memory device 201 may read-access planes PL1 to PL4 simultaneously at the maximum, the maximum plane distribution may be constituted by the planes PL1 to PL4. The read merge circuit 150 may determine that the target planes PL1 and PL2 do not constitute the maximum plane distribution.

Therefore, the read merge circuit 150 may determine to merge a background read operation for background target memory units UN23 and UN24 with the host read operation. The read merge circuit 150 may select the background target memory units UN23 and UN24 in the remaining planes PL3 and PL4 other than the existing target planes PL1 and PL2 among the planes PL1 to PL4, which constitute the maximum plane distribution.

The background read operation to be merged may be selected from the standby queue 155. The read merge circuit 150 may select the background read operation related with the planes PL3 and PL4, by referring to the background target memory units of the background read operations stored in the standby queue 155.

The background read data stored in the background target memory units UN23 and UN24 may be data which are supposed to be corrupted by various causes, for example, influence of read disturbance, interference among memory cells, elapse of a long storage time, etc. For example, the background target memory units UN23 and UN24 may be adjacent to memory units of which read counts exceed a threshold value. Hence, the controller 100 may schedule to perform the background read operation for the background target memory units UN23 and UN24, and may input the background target memory units UN23 and UN24 to the standby queue 155.

The read merge circuit 150 may merge the host read operation and the background read operation. The read merge circuit 150 may read-access the target memory units UN11, UN12, UN23 and UN24 simultaneously by merging the host read operation and the background read operation. The data stored in the target memory units UN11, UN12, UN23 and UN24 may be read simultaneously to data buffers DB1 to DB4.

The read merge circuit 150 may not consider the offset values of the target memory units UN11, UN12, UN23 and UN24 to determine the mergeability of read operations. This is because, as described above with reference to FIG. 3B, the nonvolatile memory device 201 may simultaneously access target memory units having different offset values in the planes PL1 to PL4. Therefore, the offset values of the target memory units UN11, UN12, UN23 and UN24 may be independent of one another. In other words, the positions of the target memory units UN11, UN12, UN23 and UN24 may be independent of one another.

FIG. 5 is an exemplary diagram for a method of a sequential read operation by the read merge circuit 150 in accordance with the embodiment.

Before describing FIG. 5, a host read operation may be a sequential read operation. The sequential read operation may access a plurality of target planes of two or more nonvolatile memory devices. When the sequential read operation is performed, the target memory units included in target planes may correspond to consecutive addresses. Conversely to this, a random read operation may access one target memory unit of one target plane of a certain nonvolatile memory device.

Referring to FIG. 5, when a host read operation is a sequential read operation for the nonvolatile memory devices 201 and 202, the read merge circuit 150 may group host target memory units UN31 to UN40 into one or more groups. In this regard, the read merge circuit 150 may group the host target memory units UN31 to UN40 such that each group constitutes a maximum plane distribution.

For example, the host target memory units UN31 to UN34 may become a first group because target planes PL1 to PL4 to which the host target memory units UN31 to UN34 belong constitute the maximum plane distribution, the host target memory units UN35 to UN38 may become a second group because target planes PL5 to PL8 to which the host target memory units UN35 to UN38 belong constitute the maximum plane distribution, and the remaining target memory units UN39 and UN40 may become a third group.

The read merge circuit 150 may process the third group among the first to third groups, which does not satisfy the maximum plane distribution, according to the method described above with reference to FIG. 4. That is, the read merge circuit 150 may merge an internal read operation for the planes PL3 and PL4 with the host read operation for the host target memory units UN39 and UN40.

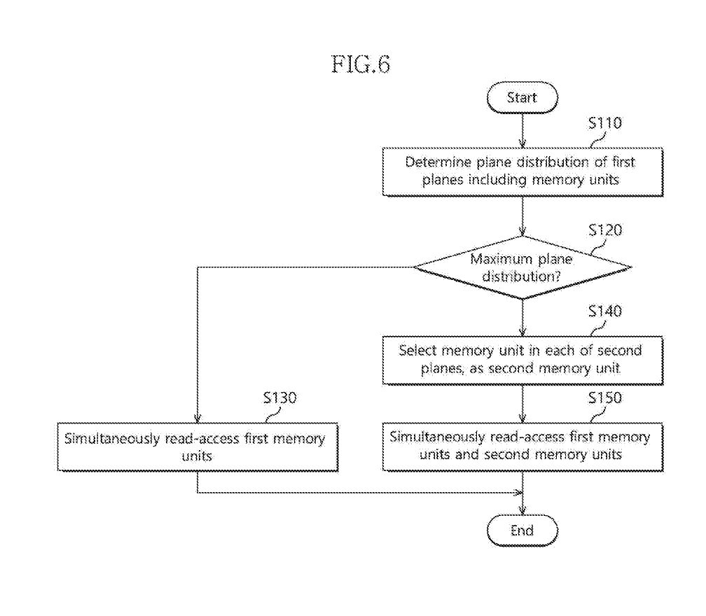

FIG. 6 is an exemplary flow chart for a method of how to operate the data storage device 10 of FIG. 1 in accordance with an embodiment.

Referring to FIG. 6, at step S110, the read merge circuit 150 may determine the plane distribution of one or more first planes which include one or more first memory units. The first memory units may be, for example, host target memory units of a host read operation. The first memory units may be, for example, background target memory units of a background read operation. The first memory units may be included in different planes, respectively, in the same nonvolatile memory device.

At step S120, the read merge circuit 150 may determine whether the plane distribution corresponds to a maximum plane distribution. The maximum plane distribution may be constituted by planes which may be read-accessed simultaneously to the maximum by the nonvolatile memory device. When the plane distribution corresponds to the maximum plane distribution, the process may proceed to step S130. When the plane distribution does not correspond to the maximum plane distribution, the process may proceed to step S140.

At the step S130, the read merge circuit 150 may read-access the first memory units simultaneously.

At the step S140, the read merge circuit 150 may select a memory unit in each of second planes as a second memory unit. The second planes may be the remaining planes other than the first planes among planes which constitute the maximum plane distribution. The memory unit selected may have a different offset value from the first memory units. The read merge circuit 150 may select a memory unit in which a background operation is scheduled to be performed, in each of the second planes, as a second memory unit. The read merge circuit 150 may select a memory unit which is adjacent to a memory unit of which a read count exceeds a threshold count, in each of the second planes, as a second memory unit.

At step S150, the read merge circuit 150 may simultaneously read-access the first memory units and second memory units. The nonvolatile memory device may simultaneously read the data stored in the first memory units and the data stored in the second memory units, to data buffers corresponding to the first planes and the second planes, respectively.

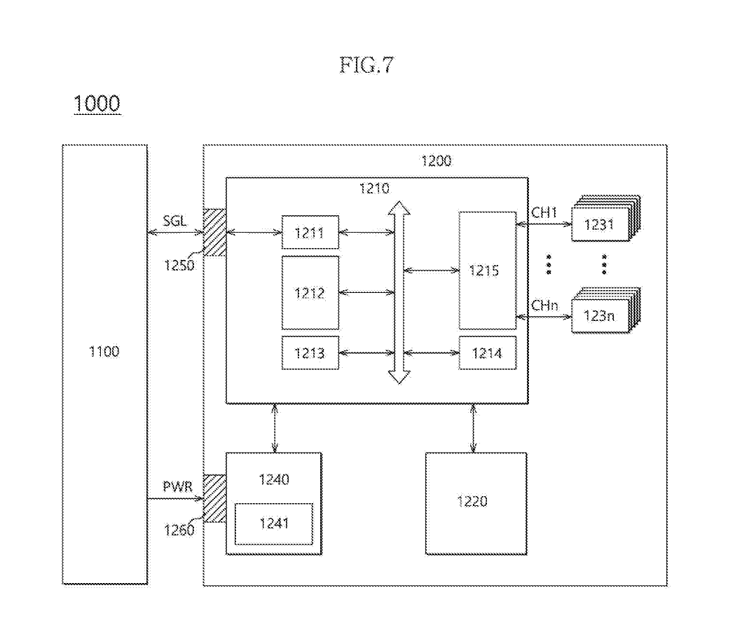

FIG. 7 is a diagram illustrating a data processing system 1000 including a solid state drive (SSD) 1200 in accordance with an embodiment. Referring to FIG. 7, the data processing system 1000 may include a host device 1100 and the SSD 1200.

The SSD 1200 may include a controller 1210, a buffer memory device 1220, a plurality of nonvolatile memory devices 1231 to 123n, a power supply 1240, a signal connector 1250, and a power connector 1260.

The controller 1210 may control general operations of the SSD 1200. The controller 1210 may include a host interface unit 1211, a control unit 1212, a random access memory 1213, an error correction code (ECC) unit 1214, and a memory interface unit 1215.

The host interface unit 1211 may exchange a signal SGL with the host device 1100 through the signal connector 1250. The signal SGL may include a command, an address, data, and so forth. The host interface unit 1211 may interface the host device 1100 and the SSD 1200 according to the protocol of the host device 1100. For example, the host interface unit 1211 may communicate with the host device 1100 through any one of standard interface protocols such as secure digital, universal serial bus (USB), multimedia card (MMC), embedded MMC (eMMC), personal computer memory card international association (PCMCIA), parallel advanced technology attachment (DATA), serial advanced technology attachment (SATA), small computer system interface (SCSI), serial attached SCSI (SAS), peripheral component interconnection (PCI), PCI express (PCI-E) and universal flash storage (UFS).

The control unit 1212 may analyze and process the signal SGL received from the host device 1100. The control unit 1212 may control operations of internal function blocks according to a firmware or a software for driving the SSD 1200. The random access memory 1213 may be used as a working memory for driving such a firmware or software.

The ECC unit 1214 may generate the parity data of data to be transmitted to at least one of the nonvolatile memory devices 1231 to 123n. The generated parity data may be stored together with the data in the nonvolatile memory devices 1231 to 123n. The ECC unit 1214 may detect an error of the data read from at least one of the nonvolatile memory devices 1231 to 123n, based on the parity data. If a detected error is within a correctable range, the ECC unit 1214 may correct the detected error.

The memory interface unit 1215 may provide control signals such as commands and addresses to at least one of the nonvolatile memory devices 1231 to 123n, according to control of the control unit 1212. Moreover, the memory interface unit 1215 may exchange data with at least one of the nonvolatile memory devices 1231 to 123n, according to control of the control unit 1212. For example, the memory interface unit 1215 may provide the data stored in the buffer memory device 1220 to at least one of the nonvolatile memory devices 1231 to 123n, or provide the data read from at least one of the nonvolatile memory devices 1231 to 123n to the buffer memory device 1220.

The buffer memory device 1220 may temporarily store data to be stored in at least one of the nonvolatile memory devices 1231 to 123n. Further, the buffer memory device 1220 may temporarily store the data read from at least one of the nonvolatile memory devices 1231 to 123n. The data temporarily stored in the buffer memory device 1220 may be transmitted to the host device 1100 or at least one of the nonvolatile memory devices 1231 to 123n according to control of the controller 1210.

The nonvolatile memory devices 1231 to 123n may be used as storage media of the SSD 1200. The nonvolatile memory devices 1231 to 123n may be coupled with the controller 1210 through a plurality of channels CH1 to CHn, respectively. One or more nonvolatile memory devices may be coupled to one channel. The nonvolatile memory devices coupled to each channel may be coupled to the same signal bus and data bus.

The power supply 1240 may provide power PWR inputted through the power connector 1260 to the inside of the SSD 1200. The power supply 1240 may include an auxiliary power supply 1241. The auxiliary power supply 1241 may supply power to allow the SSD 1200 to be normally terminated when a sudden power-off occurs. The auxiliary power supply 1241 may include large capacity capacitors.

The signal connector 1250 may be configured by various types of connectors depending on an interface scheme between the host device 1100 and the SSD 1200.

The power connector 1260 may be configured by various types of connectors depending on a power supply scheme of the host device 1100.

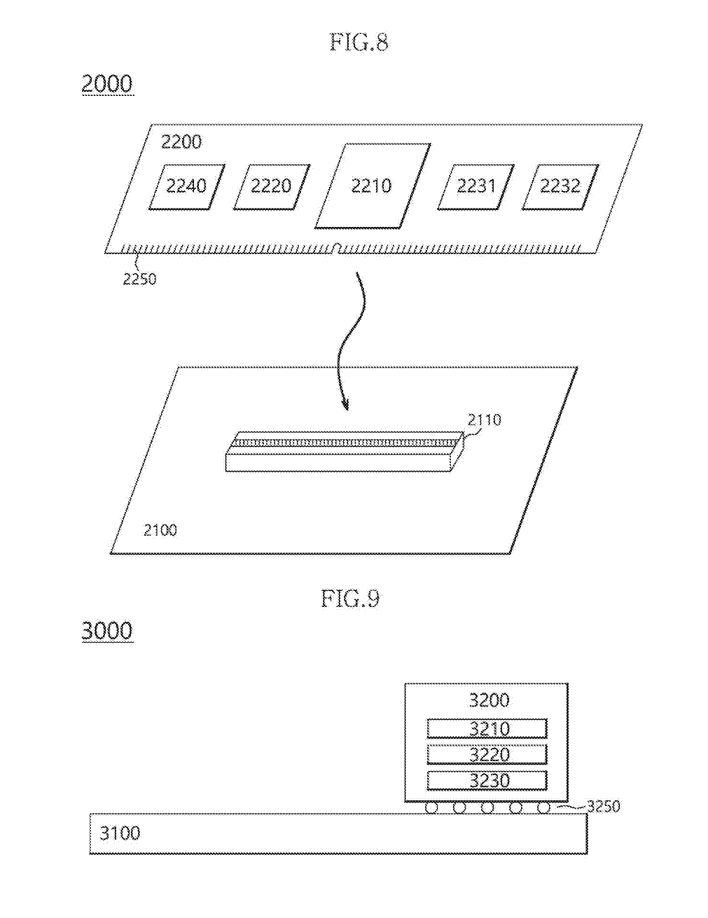

FIG. 8 is a diagram illustrating a data processing system 2000 including a memory system 2200 in accordance with an embodiment. Referring to FIG. 8, the data processing system 2000 may include a host device 2100 and the memory system 2200.

The host device 2100 may be configured in the form of a board such as a printed circuit board. Although not shown, the host device 2100 may include internal function blocks for performing the function of a host device.

The host device 2100 may include a connection terminal 2110 such as a socket, a slot or a connector. The memory system 2200 may be mounted to the connection terminal 2110.

The memory system 2200 may be configured in the form of a board such as a printed circuit board. The memory system 2200 may be referred to as a memory module or a memory card. The memory system 2200 may include a controller 2210, a buffer memory device 2220, nonvolatile memory devices 2231 and 2232, a power management integrated circuit (PMIC) 2240, and a connection terminal 2250.

The controller 2210 may control general operations of the memory system 2200. The controller 2210 may be configured in the same manner as the controller 1210 shown in FIG. 7.

The buffer memory device 2220 may temporarily store data to be stored in the nonvolatile memory devices 2231 and 2232. Further, the buffer memory device 2220 may temporarily store the data read from the nonvolatile memory devices 2231 and 2232. The data temporarily stored in the buffer memory device 2220 may be transmitted to the host device 2100 or the nonvolatile memory devices 2231 and 2232 according to control of the controller 2210.

The nonvolatile memory devices 2231 and 2232 may be used as storage media of the memory system 2200.

The PMIC 2240 may provide the power inputted through the connection terminal 2250, to the inside of the memory system 2200. The PMIC 2240 may manage the power of the memory system 2200 according to control of the controller 2210.

The connection terminal 2250 may be coupled to the connection terminal 2110 of the host device 2100. Through the connection terminal 2250, signals such as commands, addresses, data and so forth, and power may be transferred between the host device 2100 and the memory system 2200. The connection terminal 2250 may be configured into various types depending on an interface scheme between the host device 2100 and the memory system 2200. The connection terminal 2250 may be disposed on any one side of the memory system 2200.

FIG. 9 is a diagram illustrating a data processing system 3000 including a memory system 3200 in accordance with an embodiment. Referring to FIG. 9, the data processing system 3000 may include a host device 3100 and the memory system 3200.

The host device 3100 may be configured in the form of a board such as a printed circuit board. Although not shown, the host device 3100 may include internal function blocks for performing the function of a host device.

The memory system 3200 may be configured in the form of a surface-mounting type package. The memory system 3200 may be mounted to the host device 3100 through solder balls 3250. The memory system 3200 may include a controller 3210, a buffer memory device 3220, and a nonvolatile memory device 3230.

The controller 3210 may control general operations of the memory system 3200. The controller 3210 may be configured in the same manner as the controller 1210 shown in FIG. 7.

The buffer memory device 3220 may temporarily store data to be stored in the nonvolatile memory device 3230. Further, the buffer memory device 3220 may temporarily store the data read from the nonvolatile memory device 3230. The data temporarily stored in the buffer memory device 3220 may be transmitted to the host device 3100 or the nonvolatile memory device 3230 according to control of the controller 3210.

The nonvolatile memory device 3230 may be used as the storage medium of the memory system 3200.

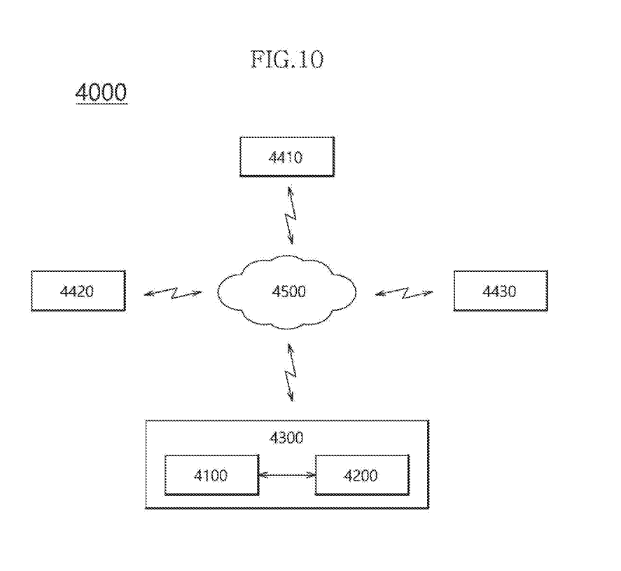

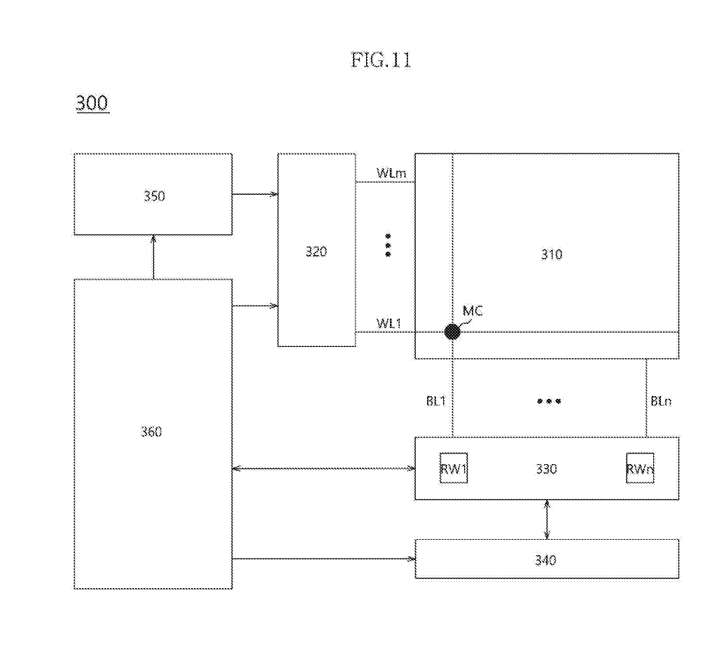

FIG. 10 is a diagram illustrating a network system 4000 including a memory system 4200 in accordance with an embodiment. Referring to FIG. 10, the network system 4000 may include a server system 4300 and a plurality of client systems 4410 to 4430 which are coupled through a network 4500.

The server system 4300 may service data in response to requests from the plurality of client systems 4410 to 4430. For example, the server system 4300 may store the data provided from the plurality of client systems 4410 to 4430. For another example, the server system 4300 may provide data to the plurality of client systems 4410 to 4430.

The server system 4300 may include a host device 4100 and the memory system 4200. The memory system 4200 may be configured by the data storage device 10 shown in FIG. 1, the memory system 1200 shown in FIG. 7, the memory system 2200 shown in FIG. 8 or the memory system 3200 shown in FIG. 9.

FIG. 11 is a block diagram illustrating a nonvolatile memory device 300 included in a memory system in accordance with an embodiment. Referring to FIG. 11, the nonvolatile memory device 300 may include a memory cell array 310, a row decoder 320, a data read/write block 330, a column decoder 340, a voltage generator 350, and a control logic 360.

The memory cell array 310 may include memory cells MC which are arranged at areas where word lines WL1 to WLm and bit lines BL1 to BLn intersect with each other.

The row decoder 320 may be coupled with the memory cell array 310 through the word lines WL1 to WLm. The row decoder 320 may operate according to control of the control logic 360. The row decoder 320 may decode an address provided from an external device (not shown). The row decoder 320 may select and drive the word lines WL1 to WLm, based on a decoding result. For instance, the row decoder 320 may provide a word line voltage provided from the voltage generator 350, to the word lines WL1 to WLm.

The data read/write block 330 may be coupled with the memory cell array 310 through the bit lines BL1 to BLn. The data read/write block 330 may include read/write circuits RW1 to RWn respectively corresponding to the bit lines BL1 to BLn. The data read/write block 330 may operate according to control of the control logic 360. The data read/write block 330 may operate as a write driver or a sense amplifier according to an operation mode. For example, the data read/write block 330 may operate as a write driver which stores data provided from the external device in the memory cell array 310 in a write operation. For another example, the data read/write block 330 may operate as a sense amplifier which reads out data from the memory cell array 310 in a read operation.

The column decoder 340 may operate according to control of the control logic 360. The column decoder 340 may decode an address provided from the external device. The column decoder 340 may couple the read/write circuits RW1 to RWn of the data read/write block 330 respectively corresponding to the bit lines BL1 to BLn with data input/output lines or data input/output buffers, based on a decoding result.

The voltage generator 350 may generate voltages to be used in internal operations of the nonvolatile memory device 300. The voltages generated by the voltage generator 350 may be applied to the memory cells of the memory cell array 310. For example, a program voltage generated in a program operation may be applied to a word line of memory cells for which the program operation is to be performed. For another example, an erase voltage generated in an erase operation may be applied to a well area of memory cells for which the erase operation is to be performed. For still another example, a read voltage generated in a read operation may be applied to a word line of memory cells for which the read operation is to be performed.

The control logic 360 may control general operations of the nonvolatile memory device 300, based on control signals provided from the external device. For example, the control logic 360 may control operations of the nonvolatile memory device 300 such as read, write and erase operations of the nonvolatile memory device 300.

While various embodiments have been described above, it will be understood to those skilled in the art that the embodiments described are examples only. Accordingly, the data storage device and the operating method thereof described herein should not be limited based on the described embodiments.

What is claimed is:

1. A data storage device comprising:
a nonvolatile memory device including a plurality of planes each of which includes a plurality of memory units; and
a controller configured to determine a plane distribution of one or more first planes which include one or more first memory units, determine whether the plane distribution satisfies a predetermined condition, select a memory unit in each of one or more second planes as a second memory unit depending on the determination result of the satisfaction of the predetermined condition, and perform a read-access in the first memory units and the second memory units simultaneously.

2. The data storage device according to claim 1,
wherein the controller determines whether the plane distribution corresponds to a maximum plane distribution when determining the predetermined condition, and
wherein the maximum plane distribution is comprised by planes which are simultaneously read-accessible to the maximum by the nonvolatile memory device.

3. The data storage device according to claim 1, wherein the second planes are not included in the plane distribution.

4. The data storage device according to claim 1, wherein the second memory units are positioned independently of the first memory units.

5. The data storage device according to claim 1, wherein the controller read data stored in the first memory units and data stored in the second memory units simultaneously to data buffers corresponding to the first planes and the second planes respectively.

6. The data storage device according to claim 1, wherein the controller selects a memory unit in which a background operation is scheduled to be performed in each of the second planes as the second memory unit.

7. The data storage device according to claim 1, wherein the controller selects a memory unit which is adjacent to a memory unit of which read count exceeds a threshold count in each of the second planes as the second memory unit.

8. The data storage device according to claim 1, wherein the controller determines to perform a read-access in the first memory units by a request of a host device.

9. The data storage device according to claim 1, wherein the controller determines to perform a read-access in the first memory units for a background operation.

10. A method for operating a data storage device including a nonvolatile memory device including a plurality of planes each of which includes a plurality of memory units, the method comprising:
determining a plane distribution of one or more first planes which include one or more first memory units;
determining whether the plane distribution satisfies a predetermined condition;
selecting a memory unit in each of one or more second planes as a second memory unit depending on the determination result of the satisfaction of the predetermined condition; and
performing read-access in the first memory units and the second memory units simultaneously.

11. The method according to claim 10, wherein the determining of whether the plane distribution satisfies the predetermined condition comprises:
determining whether the plane distribution corresponds to a maximum plane distribution,
wherein the maximum plane distribution is comprised by planes which are simultaneously read-accessible to the maximum by the nonvolatile memory device.

12. The method according to claim 10, wherein the second planes are not included in the plane distribution.

13. The method according to claim 10, wherein the second memory units are positioned independently of the first memory units.

14. The method according to claim 10, wherein the simultaneous read-access of the first memory units and the second memory units comprises:
reading data stored in the first memory units and data stored in the second memory units simultaneously to data buffers corresponding to the first planes and the second planes respectively.

15. The method according to claim 10, wherein the selecting of the memory unit comprises:
selecting a memory unit in which a background operation is scheduled to be performed in each of the second planes as the second memory unit.

16. The method according to claim 10, wherein the selecting of the memory unit comprises:
selecting a memory unit which is adjacent to a memory unit of which read count exceeds a threshold count in each of the second planes as the second memory unit.

17. The method according to claim 10, further comprising, before the determining of the plane distribution:
determining to perform a read-access in the first memory units by a request of a host device.

18. The method according to claim 10, further comprising, before the determining of the plane distribution:
determining to perform a read-access in the first memory units for a background operation.

19. A data storage device comprising:
a nonvolatile memory device including a plurality of planes, and configured to support a multi-plane read operation for the plurality of planes; and
a controller configured to process the multi-plane read operation by merging a host read operation and a background read operation,
wherein host target memory units of the host read operation and background target memory units of the background read operation have different offset values.

20. The data storage device according to claim 19, wherein planes including the host target memory units and planes including the background target memory units constitute a maximum plane distribution of the multi-plane read operation.
